(19) United States
(12) Patent Application Publication
(10) Pub. No.: US 2017/0317166 A1
(43) Pub. Date: Nov. 2, 2017

(54) ISOLATION STRUCTURES FOR CIRCUITS SHARING A SUBSTRATE

(71) Applicant: GLOBALFOUNDRIES INC., Grand Cayman (KY)

(72) Inventors: Chengwen Pei, Danbury, CT (US); Hanyi Ding, Colchester, VT (US); Ping-Chuan Wang, Hopewell Junction, NY (US); Kai D. Feng, Hopewell Junction, NY (US)

(21) Appl. No.: 15/142,838

(22) Filed: Apr. 29, 2016

(51) Int. Cl. H01L 29/06; H01L 21/76; H01L 21/3065; H01L 21/3205; H01L 21/762

(52) U.S. Cl. CPC H01L 29/0649; H01L 29/0642; H01L 21/76224; H01L 21/3065; H01L 21/32051; H01L 21/76

(57) ABSTRACT

Structures that include isolation structures and methods for fabricating isolation structures. First and second trenches are etched in a substrate and surround a device region in which an integrated circuit is formed. A dielectric material is deposited in the first trench to define a first isolation structure, and an electrical conductor is deposited in the second trench to define a second isolation structure.

### BACKGROUND

The present invention relates to integrated circuits and semiconductor device fabrication and, more specifically, to structures that include isolation structures and methods for fabricating isolation structures.

Isolation structures are used in a variety of semiconductor devices to electrically isolate devices formed on a semiconductor substrate. Shallow trench isolation relies on relatively shallow trenches filled with a dielectric material. Shallow trench isolation is commonly used to reduce parasitic capacitances and provide a relatively low level of voltage isolation between devices. Conversely, deep trench isolation utilizes relatively deep trenches. Deep trench isolation may be used to provide isolation between different types of integrated circuits sharing the same semiconductor substrate.

Improved structures that include isolation structures and methods for fabricating isolation structures are needed.

### SUMMARY

According to an embodiment, a structure has a first isolation structure comprised of a dielectric material in a first trench defined in the substrate, as well as a second isolation structure comprised of an electrical conductor in a second trench defined in the substrate. The first isolation structure and the second isolation structure surround a device region in which an integrated circuit is formed.

According to another embodiment, a method includes etching a first trench and a second trench in a substrate that surround a device region in which an integrated circuit is formed. The method further includes depositing a dielectric material in the first trench to define a first isolation structure, and depositing an electrical conductor in the second trench to define a second isolation structure.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention.

FIGS. 1-5 are cross-sectional views of a portion of a substrate at successive fabrication stages of a processing method for forming a device structure with an isolation structure in accordance with an embodiment of the invention.

FIG. 1A is a top view of the substrate portion of FIG. 1.

### DETAILED DESCRIPTION

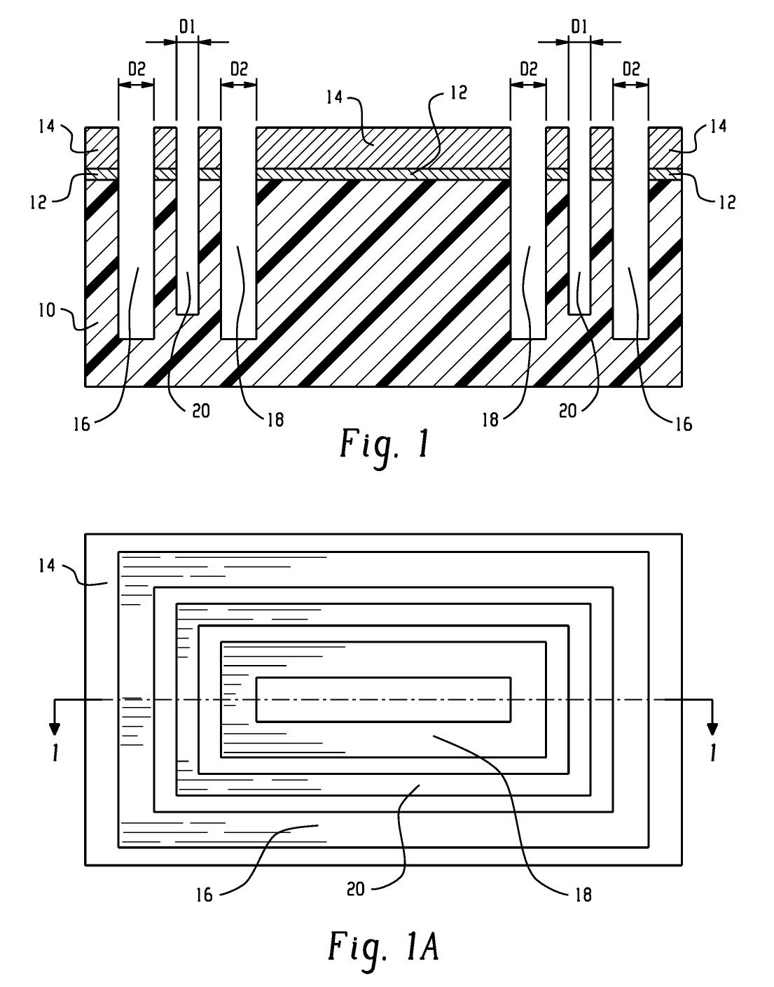

With reference to FIGS. 1, 1A and in accordance with an embodiment of the invention, a substrate 10 may be any suitable bulk substrate comprising a single-crystal semiconductor material that a person having ordinary skill in the art would recognize as suitable for forming an integrated circuit. For example, substrate 10 may be a wafer comprised of a monocrystalline silicon-containing material, such as single crystal silicon with a (100) crystal lattice orientation. The semiconductor material comprising substrate 10 may be comprised of extrinsic semiconductor material or, alternatively, may be lightly doped with an impurity to alter its electrical properties, and may also include an optional epitaxial layer. In an alternative embodiment, the substrate 10 may be a semiconductor-on-insulator (SOI) substrate. The subsequent fabrication stages apply equally using the device layer of the semiconductor-on-insulator substrate, as well as other types of bulk substrates composed of gallium nitride, silicon carbide, etc. After device structures are fabricated in product chips using the substrate 10, a dicing operation is applied to produce multiple die.

A pad layer 12 and a hardmask layer 14 are positioned on a top surface of the substrate 10. The material constituting the hardmask layer 14 may be selected to etch selectively to the semiconductor material constituting the substrate 10 and to be readily removed at a subsequent fabrication stage. In one embodiment, hardmask layer 14 may be composed of silicon dioxide (SiO₂) deposited by chemical vapor deposition (CVD). The pad layer 12 operates as a protection layer for the top surface of the substrate 10 and may be composed of, for example, silicon nitride (Si₃N₄) deposited by chemical vapor deposition.

Deep trenches, of which deep trenches 16, 18, 20 are representative, are formed by a conventional lithography and etching process at locations distributed across the surface of substrate 10. Specifically, the hardmask layer 14 is patterned using a conventional lithography and etching process. The lithography process applies a resist layer (not shown) on hardmask layer 14, exposes the resist layer to a deep trench pattern of radiation through a photomask, and develops the transferred deep trench pattern in the exposed resist to pattern resist layer. The deep trench pattern is transferred to the hardmask layer 14 using the patterned resist layer as an etch mask for an anisotropic dry etching process, such as a reactive-ion etching (ME) process or a plasma etching process. The etching process removes portions of the hardmask layer 14 exposed through the deep trench pattern in the patterned resist and stops vertically on pad layer 12. The deep trench pattern is then transferred by an etching process from the patterned hardmask layer 14 through the pad layer 12 and into the semiconductor material of the substrate 10 with an anisotropic dry etching process, such as reactive ion etching (ME). The etching process may be conducted in a single etching step or multiple etching steps with different etch chemistries. For example, an etch chemistry capable of removing the constituent semiconductor material selective to (i.e., with a significantly greater etch rate than) the material(s) constituting the hardmask layer 14 is employed to extend the pattern into the substrate 10.

The deep trenches 16, 18 have different dimensions than the deep trench 20. Specifically, deep trenches 16, 18 each have a trench width (e.g., critical dimension) that is greater than a crucial dimension of the deep trench 20, which results in the deep trenches 16, 18 penetrating to a deeper depth into the substrate 10 than the deep trench 20. The respective trench widths may be assessed in a plane parallel to a plane including a top surface of the substrate 10. The widths and depths of the deep trenches 16, 18 and the deep trench 20 are determined during photolithography when the hardmask layer 14 is patterned. The deep trench 20 has a trench width D1 and the deep trenches 16, 18 have a trench width D2 that is greater than the trench width of the deep trench 20. In exemplary embodiment, the trench width of the deep trenches 16, 18 may be in a range of 80 nm to 1000 nm and the trench width of the deep trench 20 may be in a range of 30 nm to 100 nm.

The deep trenches 16, 18, 20 may have a concentric or a non-concentric arrangement, as specific applications require, with the deep trench 20 being located between deep trench 16 and deep trench 18. The deep trench 16 is arranged as the outermost of the deep trenches 16, 18, 20 and traces a ring having the largest circumference. The deep trench 18 is arranged as the innermost of the deep trenches 16, 18, 20 and traces a ring having the smallest circumference. Deep trench 18 is located interior of deep trench 20, and deep trenches 18, 20 are located interior of deep trench 16. Embodiments of the invention are not limited to the specific number of deep trenches in the representative embodiment.

With reference to FIG. 2 in which like reference numerals refer to like features in FIG. 1 and at a subsequent fabrication stage, a dielectric material is deposited that fills the deep trench 20 with an isolation structure 22 and that deposits a layer 24 on the walls of the deep trenches 16, 18. The isolation structure 22 conforms to the shape of the deep trench 20. The deposited dielectric material may be removed from the top surface of the hardmask layer 14 by chemical-mechanical polishing (CMP) or another suitable planarization technique. The dielectric material may comprise silicon oxide (SiO₂), and may be deposited by, for example, metal organic chemical vapor deposition (MOCVD) or plasma-enhanced chemical vapor deposition (PECVD). The isolation structure 22 may improve DC isolation between different circuits that share the substrate 10 but that are separated from each other by the isolation structure 22.

The layer 24 forms inside deep trenches 16, 18 concurrently with the formation of the isolation structure 22 when the dielectric material is deposited. The layer 24 dads the sidewalls of the deep trenches 16, 18 because of the larger trench width in comparison with deep trench 20. The deposition time may be controlled to prevent complete filling with dielectric material. Consequently, the deep trenches 16, 18 are only partially filled by the deposited dielectric material.

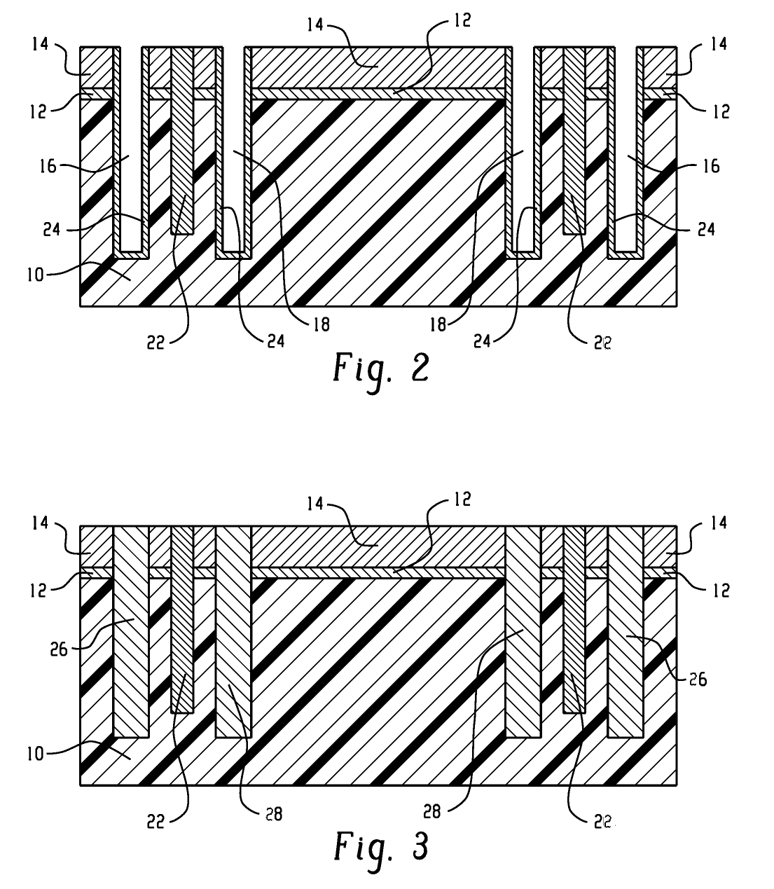

With reference to FIG. 3 in which like reference numerals refer to like features in FIG. 2 and at a subsequent fabrication stage, the layer 24 may be optionally removed from inside the deep trenches 16, 18 using a selective etching process. The etching process may be a wet chemical process using either dilute hydrofluoric (DHF) or buffered hydrofluoric (BHF), or a dry process, such as chemical oxide removal (COR). Since deep trench 20 is completely filled, the isolation structure 22 inside deep trench 20 is only negligibly etched, but may be slightly recessed over the etch time required to remove layer 24.

An electrical conductor is deposited that concurrently fills the deep trenches 16, 18 with respective isolation structures 26, 28. The isolation structure 22 physically blocks the electrical conductor from being deposited inside of deep trench 20. The deposited electrical conductor may be removed from the top surface of the hardmask layer 14 by chemical-mechanical polishing or another suitable planarization technique. Suitable electrical conductors include, but are not limited to, copper (Cu), aluminum (Al), tungsten (W), cobalt (Co), titanium (Ti), alloys of these metals, and other similar metals, which may be deposited by a deposition processes including, but not limited to chemical vapor deposition or an electrochemical process like electroplating or electroless plating. A barrier layer (not shown) may be deposited on the trench sidewalls of deep trenches 16, 18 before the primary electrical conductor is deposited to form the isolation structures 26,28. The barrier layer may comprise, for example, titanium nitride, a bilayer of titanium and titanium nitride, etc. The isolation structures 26, 28 may provide improved the radiofrequency isolation between different circuits that share the substrate 10.

The isolation structures 26, 28 conform to the shape of their respective deep trenches 16, 18. The isolation structures 22, 26, 28 are arranged such that isolation structure 22 is disposed between isolation structure 26 and isolation structure 28. Isolation structure 28 is located interior of isolation structure 22, and isolation structures 22, 28 are located interior of isolation structure 26.

In the representative embodiment, one of the isolation structures 22, 26, 28 includes, as a fill material, a dielectric material that is an electrical insulator and two of the isolation structures 22, 26, 28 include, as a fill material, a metal that is electrically conductive. However, in alternative embodiments, the number and fill material of the isolation structures may vary. As examples, one of the isolation structures 26, 28 may be eliminated so that only a single isolation structure of each fill-type remains, or one of the isolation structures 26, 28 may be converted to a narrower dimension by formation in a narrower trench so that it provides another dielectric-filled isolation structure. The isolation structures 22, 26, 28 may have a different arrangement such that the isolation structure 22 is the innermost of the set of three isolation structures 22, 26, 28. Generally, the structure represented by the embodiments of the invention include at least one isolation structure like isolation structure 22 and at least one isolation structure like isolation structures 26, 28. In an embodiment, the structure may include only a single dielectric-filled isolation structure and a single conductor-filled isolation structure that is either interior or exterior of the single dielectric-filled isolation structure.

In an alternative embodiment, the layer 24 of dielectric material may not be removed from the trench sidewalls and may remain resident on the trench sidewalls during subsequent fabrication stages that form the isolation structures 26, 28. As a result, the layer 24 will separate the electrical conductor (e.g., metal) of the isolation structures 26, 28 from the surrounding semiconductor material of the substrate 10.

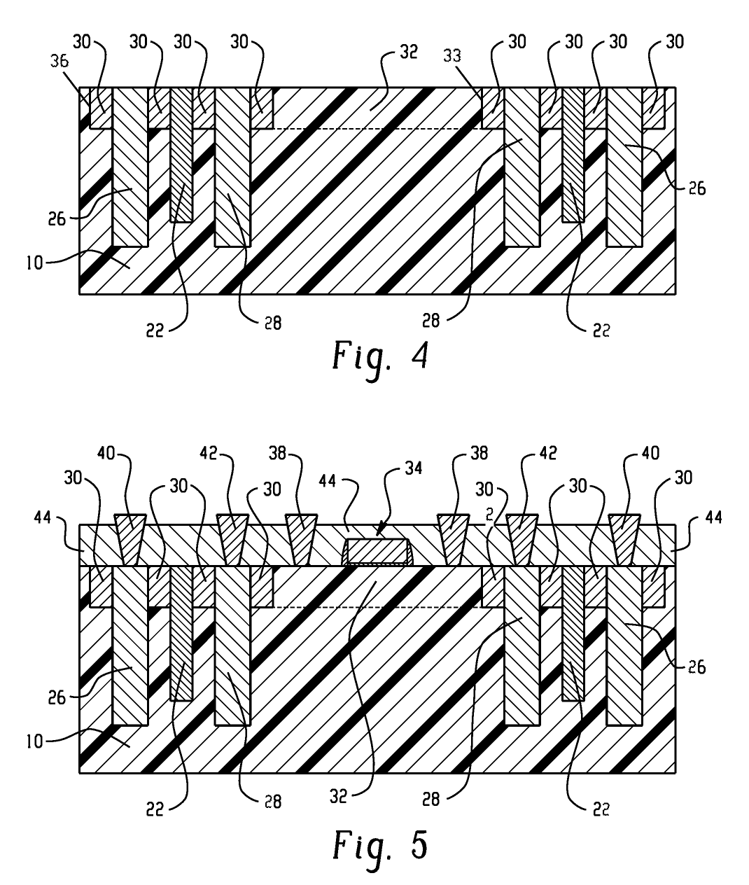

With reference to FIG. 4 in which like reference numerals refer to like features in FIG. 3 and at a subsequent fabrication stage, the hardmask layer 14 may be removed, followed by the formation of one or more trench isolation regions 30 in the substrate 10. The trench isolation regions 30 border a device region 32 of the substrate 10 that may be used to fabricate one or more device structure and/or one or more integrated circuits, and establish an outer boundary 33 for the device region 32. The outer boundary 33 for the device region is also the inner boundary for the trench isolation regions 30. The device region 32 is located interior of the innermost deep trench 18 and the isolation structure 28 occupying deep trench 18. Isolation structure 28 is located interior of isolation structures 22, 26 such that isolation structure 28 is closer to the device region 32 than the isolation structures 22, 26. Isolation structure 22 is located interior of the isolation structure 26 such that the isolation structure 22 is closer to the device region 32 than the isolation structure 26. The isolation structures 22, 26, 28 are located between the inner boundary 33 and an outer boundary 36 of the trench isolation regions 30.

The trench isolation regions 30 may be formed by a shallow trench isolation (STI) technique that relies on a photolithography and reactive ion etching process to define trenches in substrate 10, deposits an electrical insulator to fill the trenches, and planarizes the electrical insulator relative to the top surface of the substrate 10 using, for example, chemical mechanical polishing. The electrical insulator may be comprised of an oxide of silicon deposited by chemical vapor deposition. The pad layer 12 may be removed after the trench isolation regions 30 are formed. The etching process used to form the trench isolation regions 30 removes the material of the substrate 10 selective to (i.e., with a higher etch rate than) the materials of the isolation structures 22, 26, 28. The isolation structures 22, 26, 28 penetrate through the thickness of the trench isolation regions 30, which are formed in trenches that are shallower than the deep trenches 16, 18, 20.

With reference to FIG. 5 in which like reference numerals refer to like features in FIG. 4 and at a subsequent fabrication stage, an integrated circuit, generally indicated by reference numeral 34, may be formed using the device region 32. The integrated circuit 34 may include devices such as the representative planar field-effect transistor and may be formed by complementary metal-oxide-semiconductor (CMOS) processes. Additional integrated circuits may be formed using other areas of the substrate 10 that are exterior of the outermost isolation structure 26 such that all of the isolation structures 22, 26, 28 are located between the integrated circuit 34 located in device region 32 and the integrated circuits located in these other areas of the substrate 10 outside of the device region 32. The isolation structures 22, 26, 28 surround the device region 32 in that each extends about the entire outer boundary 33 (FIG. 4) of the device region 32. The isolation structures 22, 26, 28 form closed shapes that have segments or sections that are located on all sides of the device region 32. The isolation structures 22, 26, 28 and the trench isolation regions 30 are located between the integrated circuit 34 and another integrated circuit that is exterior of the trench isolation regions 30.

Middle-of-line (MOL) processing and back-end-of-the-line (BEOL) processing follows, which includes silicide formation, and formation of contacts and wiring. During middle-of-line processing, contacts 38, 40, 42 may be formed in contact vias defined in a dielectric layer 44 as parts of the local interconnect structure and in accordance with an interconnect layout. One or more contacts 38 are aligned and coupled with portions of the a device of the integrated circuit 34, one or more contacts 40 are aligned and coupled with the isolation structure 26, and one or more contacts 42 are aligned and coupled with the isolation structure 28. Each set of one or more contacts 38, 40, 42 may comprise an array of vias (e.g., round vias) that are arranged with a given pitch or may comprise a bar via. The contacts 38, 40, 42 are comprised of a conductor, such as a refractory metal like tungsten, and the contact vias can be lined with a titanium-based or tungsten-based barrier layer. The contacts 38, 40, 42 may be formed by depositing a layer of the metal using, for example, physical vapor deposition and then planarizing the metal layer with, for example, chemical mechanical polishing to remove excess metal from the top surface of dielectric layer 44. The dielectric layer 44 may be comprised of silicon nitride, a different dielectric material, or a combination of dielectric materials. In an embodiment, the contacts 40, 42 may be coupled with a ground potential.

The isolation structures 22, 26, 28 may function to reduce substrate coupling, particularly for large scale integrated circuits, such as a system-on-chip that integrates all components of an electronic system into a single chip. A system-on-chip may include digital, analog, mixed-signal, and/or radiofrequency circuits sharing a single chip substrate. The isolation structures 22, 26, 28, which present metal-filled and dielectric-filled deep trench pair ring or multiple ring structures, may function to reduce an amount of interference that is coupled from one circuit to another circuit. For example, the metal rings provided by the isolation structures 26, 28 may improve radiofrequency isolation on a shared substrate. As another example, dielectric ring provided by the isolation structure 22 may improve DC isolation, which may in turn improve circuit isolation on a shared substrate. In this instance, the isolation structures 22, 26, 28 are located between the integrated circuit 34 and another integrated circuit that is located exterior or outside of the outer boundary 36 of the trench isolation regions 30.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refers to a direction perpendicular to the horizontal, as just defined. The term “lateral” refers to a direction within the horizontal plane. Terms such as “above” and “below” are used to indicate positioning of elements or structures relative to each other as opposed to relative elevation.

A feature may be “connected” or “coupled” to or with another element may be directly connected or coupled to the other element or, instead, one or more intervening elements may be present. A feature may be “directly connected” or “directly coupled” to another element if intervening elements are absent. A feature may be “indirectly connected” or “indirectly coupled” to another element if at least one intervening element is present.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A structure formed in a substrate, the structure comprising:
a first isolation structure comprised of a dielectric material in a first trench defined in the substrate;
a second isolation structure comprised of an electrical conductor in a second trench defined in the substrate;
a device region of the substrate that is entirely surrounded by the first isolation structure and by the second isolation structure; and
an integrated circuit in the device region.

2. The structure of claim 1 further comprising:
a layer comprised of the dielectric material on sidewalls of the second trench, the layer positioned between the electrical conductor and the substrate surrounding the second trench.

3. The structure of claim 1 wherein the first trench penetrates to a first depth into the substrate, the second trench penetrates to a second depth into the substrate, and the second depth is greater than the first depth.

4. The structure of claim 3 wherein the first trench has a first trench width in a plane perpendicular to the first depth, the second trench has a second trench width in a plane perpendicular to the second depth, and the second trench width is greater than the first trench width.

5. (canceled)

6. The structure of claim 1 wherein the first isolation structure is located interior of the second isolation structure such that the first isolation structure is closer to the device region than the second isolation structure.

7. The structure of claim 1 wherein the second isolation structure is located interior of the first isolation structure such that the second isolation structure is closer to the device region than the first isolation structure.

8. The structure of claim 1 further comprising:
a third isolation structure comprised of the electrical conductor in a third trench defined in the substrate,
wherein the device region is surrounded by the third isolation structure.

9. (canceled)

10. The structure of claim 1 further comprising:
one or more contacts coupled with the electrical conductor of the second isolation structure.

11. A method comprising:
etching a first trench in a substrate that entirely surrounds a device region in which an integrated circuit is to be formed;
etching a second trench in the substrate that entirely surrounds the device region;
depositing a dielectric material in the first trench to define a first isolation structure; and
depositing an electrical conductor in the second trench to define a second isolation structure.

12. The method of claim 11 further comprising:
forming a layer comprised of the dielectric material on sidewalls of the second trench when the dielectric material is deposited in the first trench,
wherein the layer is positioned between the electrical conductor and the substrate surrounding the second trench.

13. The method of claim 11 wherein the first trench penetrates to a first depth into the substrate, the second trench penetrates to a second depth into the substrate, and the second depth is greater than the first depth.

14. The method of claim 13 wherein the first trench has a first trench width in a plane perpendicular to the first depth, the second trench has a second trench width in a plane perpendicular to the second depth, and the second trench width is greater than the first trench width.

15. (canceled)

16. The method of claim 11 wherein the first isolation structure is located interior of the second isolation structure such that the first isolation structure is closer to the device region than the second isolation structure.

17. The method of claim 11 wherein the second isolation structure is located interior of the first isolation structure such that the second isolation structure is closer to the device region than the first isolation structure.

18. The method of claim 11 further comprising:
etching a third trench in the substrate that surrounds the device region; and
depositing the electrical conductor in the third trench to define a third isolation structure concurrent with the deposition of the electrical conductor in the second trench.

19. (canceled)

20. The method of claim 11 further comprising:
forming one or more contacts that are coupled with the electrical conductor of the second isolation structure.

21. The structure of claim 1 further comprising:
a shallow trench isolation region in the substrate,
wherein the shallow trench isolation region is comprised of an electrical insulator, the first isolation structure penetrates through the shallow trench isolation region into the substrate, and the second isolation structure penetrates through the shallow trench isolation region into the substrate.

22. The structure of claim 21 wherein the first trench penetrates to a first depth into the substrate, the second trench penetrates to a second depth into the substrate, the shallow trench isolation region penetrates to a third depth that is shallower than the first depth and that is shallower than the second depth.

23. The method of claim 11 further comprising:
forming a shallow trench isolation region in the substrate,
wherein the shallow trench isolation region is comprised of an electrical insulator, the first isolation structure penetrates through the shallow trench isolation region into the substrate, and the second isolation structure penetrates through the shallow trench isolation region into the substrate.

24. The method of claim 23 wherein the first trench penetrates to a first depth into the substrate, the second trench penetrates to a second depth into the substrate, the shallow trench isolation region penetrates to a third depth that is shallower than the first depth and that is shallower than the second depth.
